(19) United States
(12) Patent Application Publication
(10) Pub. No.: US 2026/0171156 A1
(43) Pub. Date: Jun. 18, 2026

(54) STORAGE CONTROLLER, STORAGE DEVICE, AND OPERATING METHOD FOR WORD-LINE GROUP-BASED SUSPEND MANAGEMENT

(71) Applicant: Samsung Electronics Co., Ltd., Suwon-si (KR)

(72) Inventors: Jiwoo Park, Suwon-si (KR); Jinwoo Hong, Suwon-si (KR); Sejong Kim, Suwon-si (KR); Sunghwan Bae, Suwon-si (KR); Seona Won, Suwon-si (KR)

(21) Appl. No.: 19/409,022

(22) Filed: Dec. 4, 2025

(30) Foreign Application Priority Data
Dec. 18, 2024 (KR) 10-2024-0190460

(51) Int. Cl. G11C 16/08; G11C 16/10; G11C 16/26

(52) U.S. Cl. CPC G11C 16/08; G11C 16/102; G11C 16/26

(57) ABSTRACT

An operating method of a storage device including a storage controller and a memory device includes performing, a word line (WL) grouping operation for classifying word lines connected to memory cells having similar physical characteristics into a same group, based on status information. A maximum cancel count of each of a plurality of groups is determined. A suspend command is received and a current cancellation count of a first word line corresponding to the suspend command is compared with a maximum cancel count of a group including the first word line. Based on the comparison the storage device operates in a first mode of a suspend operation when the current cancellation count is less than the maximum cancel count and operates in a second mode of the suspend operation when the current cancellation count is greater than or equal to the maximum cancel count.

### CROSS-REFERENCE TO RELATED APPLICATION

This application is based on and claims priority under 35 USC § 119 to Korean Patent Application No. 10-2024-0190460, filed on Dec. 18, 2024, in the Korean Intellectual Property Office, the disclosure of which is incorporated by reference herein in its entirety.

### BACKGROUND

This disclosure relates to semiconductor memory, and more particularly, to a storage controller, a storage device, and an operating method of the storage device.

Semiconductor memory is classified into volatile memory devices, such as static random access memory (SRAM) and dynamic random access memory (DRAM), which lose stored data when power is cut off, and nonvolatile memory devices, such as flash memory devices, phase-change random access memory (PRAM), magnetoresistive random access memory (MRAM), resistive random access memory (RRAM), and ferroelectric random access memory (FRAM), which retain stored data even when power is cut off.

Flash memory has been widely used as a storage device, which is a large-capacity storage medium. Storage devices store data under control by a host device, such as a computer, smartphone, or smart pad. Storage devices include devices that store data on magnetic disks, such as hard disk drives (HDDs), and devices that store data on semiconductor memory, particularly, nonvolatile memory, such as solid state drives (SSDs) and memory cards.

### SUMMARY

This disclosure provides a storage controller, a storage device, and an operating method of the storage device capable of providing stable write performance.

For storage devices, data write latency may vary significantly depending on the physical characteristics of memory cells, the complexity of a program algorithm, and internal operating methods. This variable write latency may be a major cause of system performance degradation and data processing delay.

To address this, demand for storage device design and operating methods that may guarantee constant write latency has continuously increased. In particular, the development of technology that reduces program latency deviation between word lines and provides stable write performance even under specific data storage conditions is required.

According to an aspect of this disclosure, there is provided an operating method of a storage device including a storage controller and a memory device, including performing, by the storage controller, a word line (WL) grouping operation for classifying word lines connected to memory cells having similar physical characteristics into a same group, based on status information, determining, by the storage controller, a maximum cancel count of each of a plurality of groups, receiving, by the memory device, a suspend command, comparing, by the memory device, a current cancellation count of a first word line corresponding to the suspend command with a maximum cancel count of a group including the first word line, operating, by the memory device, in a first mode of a suspend operation when the current cancellation count is less than the maximum cancel count, and operating, by the memory device, in a second mode of the suspend operation when the current cancellation count is greater than or equal to the maximum cancel count, wherein the first mode refers to a mode in which a currently executed program loop is immediately stopped and a read operation is performed, and the second mode refers to a mode in which the currently executed program loop is continued and a read operation is performed after the program loop is completed.

According to another aspect of this disclosure, there is provided a storage device including a memory device and a storage controller configured to control the memory device and communicate with an external host, the storage controller including a suspend manager, wherein the suspend manager includes a status monitor configured to obtain status information, a word line (WL) group generator configured to perform a WL grouping operation to classify word lines connected to memory cells having similar physical characteristics into a same group, based on the status information, and a maximum cancel count determiner configured to determine a maximum cancel count of each of the plurality of groups, and wherein the memory device is configured to receive a suspend command from the storage controller, compare a current cancellation count of a first word line corresponding to the suspend command with a maximum cancel count of a group including the first word line and operate in a first mode of a suspend operation when the current cancellation count is less than the maximum cancel count, and operates in a second mode of the suspend operation when the current cancellation count is greater than or equal to the maximum cancel count, and wherein the first mode refers to a mode in which a program loop being currently executed is immediately stopped and a read operation is performed, and the second mode refers to a mode in which the program loop being currently executed is continued and a read operation is performed after the program loop is completed.

According to another aspect of this disclosure, there is provided an operating method of a storage controller including obtaining status information including physical characteristic information of memory cells of an external memory device, performing a word line (WL) grouping operation of classifying word lines connected to memory cells having similar physical characteristics into a same group, based on the status information, and determining a maximum cancel count of each of a plurality of groups.

### BRIEF DESCRIPTION OF THE DRAWINGS

Implementations will be more clearly understood from the following detailed description taken in conjunction with the accompanying drawings in which:

FIG. 1 is a block diagram illustrating a storage device according to some implementations;

FIG. 2 is a block diagram illustrating a nonvolatile memory of FIG. 1.

FIG. 3 is a block diagram illustrating an example of a memory block of FIG. 2;

FIG. 4 is a block diagram illustrating a suspend manager of FIG. 1 in detail;

FIGS. 5A to 5C are diagrams illustrating a suspend manager;

FIG. 6 is a flowchart illustrating an example of an operation of the suspend manager of FIG. 1;

FIG. 7 is a flowchart illustrating an example of an operation of the storage device of FIG. 1;

FIG. 8 is a flowchart illustrating an example of an operation of a memory device of FIG. 1;

FIG. 9 is a flowchart illustrating an example of the operation of the memory device of FIG. 1;

FIG. 10 is a timing diagrams illustrating a program operation of the memory device of FIG. 1;

FIG. 11 is a flowchart illustrating operation S330 of FIG. 8 in detail;

FIG. 12 is a flowchart illustrating operation S340 of FIG. 8 in detail;

FIG. 13 is a flowchart illustrating an example of an operation of the suspend manager of FIG. 1;

FIGS. 14 and 15 are diagrams illustrating a suspend operation of the memory device of FIG. 1;

FIG. 16 is a graph illustrating an example of the relationship between a word line and characteristic information in the memory device of FIG. 1;

FIG. 17 is a graph illustrating the effect of an adaptive suspend operation; and

FIG. 18 is a diagram illustrating a system according to some implementations.

### DETAILED DESCRIPTION

Hereinafter, implementations are described clearly and in detail to such an extent that a person skilled in the art may easily practice this disclosure.

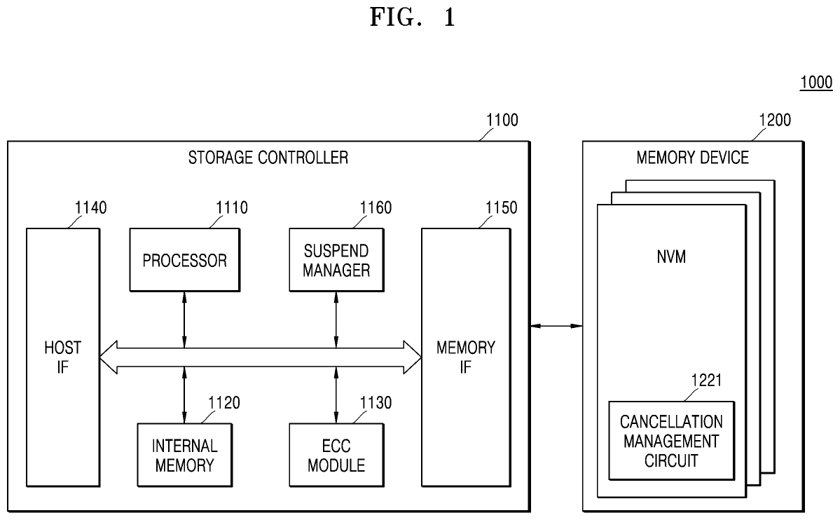

FIG. 1 is a block diagram illustrating a storage device 1000 according to some implementations.

Referring to FIG. 1, the storage device 1000 may include a storage controller 1100 and a memory device 1200. The storage controller 1100 may operate under control by an external host. For example, the storage controller 1100 may store data in the memory device 1200 or provide the data stored in the memory device 1200 to the host under control by the external host.

The storage controller 1100 may include a processor 1110, an internal memory (or a buffer memory) 1120, an error correction code (ECC) module (or an ECC engine) 1130, a host interface (IF) circuit 1140, a memory IF circuit 1150, and a suspend manager 1160.

The processor 1110 may control all operations of the storage controller 1100. For example, the processor 1110 may run an operating system or firmware to drive the storage controller 1100. The processor 1110 may generate commands and addresses for controlling the memory device 1200, based on a request from the host. The processor 1110 may execute one or more instructions stored in the internal memory 1120. The processor 1110 may run an operating system or firmware to drive the storage controller 1100.

The internal memory 1120 may temporarily store data to be stored in the memory device 1200 or data read from the memory device 1200. The internal memory 1120 may be configured to store various information necessary for the storage controller 1100 to operate. For example, the internal memory 1120 may be configured to store a map table for accessing the memory device 1200. The internal memory 1120 may store one or more instructions. In some implementations, the internal memory 1120 may include random access memory. For example, the internal memory 1120 may include static random access memory (SRAM) or dynamic random access memory (DRAM).

The ECC module 1130 may perform ECC encoding on user data to be stored in the memory device 1200 to generate parity data. The generated parity data may be stored in the memory device 1200 together with the user data. The ECC module 1130 may be configured to perform ECC decoding based on the user data and the parity data read from the memory device 1200 to correct errors in the user data.

The host IF circuit 1140 may be configured to communicate with the host. In some implementations, the host IF circuit 1140 may be configured to comply with a predefined interface, communication protocol, or communication standard between the host and the storage device 1000. The predefined interface may support at least one of various interfaces, such as universal serial bus (USB), small computer system interface (SCSI), PCI express, advanced technology attachment (ATA), parallel ATA (PATA), serial ATA (SATA), serial attached SCSI (SAS), universal flash storage (UFS), nonvolatile memory express (NVMe), compute express link (CXL), etc., but the scope of this disclosure is not limited thereto.

The memory IF circuit 1150 may be configured to access the memory device 1200. For example, the memory IF circuit 1150 may be configured to access the memory device 1200 based on commands and addresses generated by the processor 1110 to control the memory device 1200. In some implementations, the memory IF circuit 1150 may communicate with the memory device 1200 based on an interface or protocol determined based on standards or determined by a manufacturer. In some implementations, the interface or protocol described above may include a toggle interface or an open NAND flash interface (ONFI).

The memory device 1200 may operate under control by the storage controller 1100. The memory device 1200 may include a plurality of nonvolatile memories NVM. In some implementations, the plurality of nonvolatile memories NVM included in the memory device 1200 may communicate with the storage controller 1100 through a plurality of channels and form a plurality of ways. In some implementations, the memory device 1200 may be configured based on NAND flash memory. However, the scope of this disclosure is not limited thereto, and the memory device 1200 may be configured based on at least one of various nonvolatile memory devices, such as a phase change memory device, a ferroelectric memory device, a magnetic memory device, a resistive memory device, and the like.

The suspend manager 1160 may obtain status information. The suspend manager 1160 may obtain status information including physical characteristic information of memory cells of the memory device 1200 (or the nonvolatile memory NVM. The suspend manager 1160 may perform a word line (WL) grouping operation. The suspend manager 1160 may classify word lines with similar physical characteristics as a same group. The suspend manager 1160 may perform a maximum cancel count determination operation. The suspend manager 1160 may determine a maximum cancel count per group.

The storage controller 1100 may transmit a suspend command to the memory device 1200. The storage controller 1100 may transmit a suspend command to the memory device 1200 to provide target performance of the external host or to provide a required read latency or write latency. For example, the storage controller 1100 may transmit a suspend command to the memory device 1200 during a program operation to satisfy read latency. The storage controller 1100 may transmit a read command after the suspend command. The storage controller 1100 may transmit read data corresponding to a read command to the external host. The storage controller 1100 may transmit a resume command to the memory device 1200 to resume a stopped operation. The storage controller 1100 may reduce read latency through the suspend command.

The nonvolatile memory NVM included in the memory device 1200 may include a cancellation management circuit 1221. The memory device 1200 may receive the suspend command. For example, the suspend command may be a command that requests stop of an operation of a command currently being processed. Alternatively, the suspend command may be a command that requests stop of an operation currently being performed. For example, the memory device 1200 may receive the suspend command while performing the program operation. The memory device 1200 may stop the program operation in response to the suspend command.

The memory device 1200 may experience program latency deviation (or difference) between word lines due to differences in physical characteristics of memory cells. Due to differences in the physical characteristics of memory cells in the memory device 1200, there may be differences in the number of incremental step pulse programming (ISPP) program loops between word lines. Accordingly, write latency deviation of the memory device 1200 may occur, which may deteriorate write consistency.

The memory device 1200 according to some implementations may perform an adaptive suspend operation. The memory device 1200 may perform the adaptive suspend operation, based on physical characteristics thereof. The memory device 1200 may perform the adaptive suspend operation, based on a maximum cancel count per word line (or per group) provided by the storage controller 1100. Accordingly, the memory device 1200 may provide a constant write latency. The memory device 1200 may improve write consistency. Below, the WL grouping operation, maximum cancel count determination operation, and adaptive suspend operation are described in more detail.

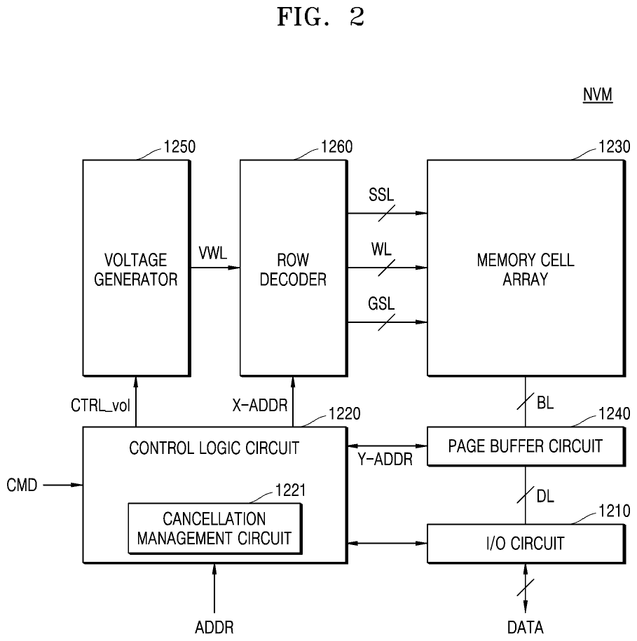

FIG. 2 is a block diagram illustrating the nonvolatile memory NVM of FIG. 1.

In some implementations, the nonvolatile memory NVM of FIG. 2 may correspond to one of a plurality of nonvolatile memories included in the memory device of FIG. 1. That is, the storage device 1000 may further include nonvolatile memories having a structure similar to that of the nonvolatile memory NVM of FIG. 2.

Referring to FIGS. 1 and 2, the nonvolatile memory NVM may include an input/output (I/O) circuit 1210, a control logic circuit 1220, a memory cell array 1230, a page buffer circuit 1240, a voltage generator 1250, and a row decoder 1260. Although not shown in FIG. 2, the nonvolatile memory NVM may further include a column logic, a pre-decoder, a temperature sensor, a command decoder, an address decoder, etc.

The control logic circuit 1220 may generally control various operations within the nonvolatile memory NVM. The control logic circuit 1220 may output various control signals in response to a command CMD and/or address ADDR from the I/O circuit 1210. For example, the control logic circuit 1220 may output a voltage control signal CTRL_vol, a row address X-ADDR, and a column address Y-ADDR.

The memory cell array 1230 may include a plurality of memory blocks, and each of the plurality of memory blocks may include a plurality of memory cells. The memory cell array 1230 may be connected to the page buffer circuit 1240 via bit lines BL and to the row decoder 1260 via word lines WL, string select lines SSL, and ground select lines GSL.

In some implementations, the memory cell array 1230 may include a three-dimensional (3D) memory cell array, and the 3D memory cell array may include a plurality of NAND strings. Each NAND string may include memory cells respectively connected to word lines stacked vertically on a substrate. U.S. Pat. Nos. 7,679,133, 8,553,466, 8,654,587, 8,559,235, and U.S. Application Publication No. 2011/0233648 are incorporated herein by reference in their entirety. In some implementations, the memory cell array 1230 may include a two-dimensional (2D) memory cell array, and the 2D memory cell array may include a plurality of NAND strings arranged in the row and column directions.

The page buffer circuit 1240 may include a plurality of n page buffers (n is an integer greater than or equal to 3). The page buffer circuit 1240 may be connected to the memory cell array 1230 via bit lines. The plurality of page buffers of the page buffer circuit 1240 may be respectively connected to memory cells through a plurality of bit lines BL. The page buffer circuit 1240 may select at least one bit line among the bit lines BL in response to the column address Y-ADDR. The page buffer circuit 1240 may operate as a write driver or a sense amplifier depending on an operating mode. For example, during a program operation, the page buffer circuit 1240 may apply a bit line voltage corresponding to data to be programmed to a selected bit line. During a read operation, the page buffer circuit 1240 may detect data stored in a memory cell by detecting current or voltage of the selected bit line.

The voltage generator 1250 may generate various types of voltages for performing program, read, and erase operations, based on the voltage control signal CTRL_vol. For example, the voltage generator 1250 may generate, as a word line voltage VWL, a program voltage, a read voltage, a program verify voltage, an erase voltage, etc.

The row decoder 1260 may select one of a plurality of word lines WL and one of a plurality of string select lines SSL in response to the row address X-ADDR. For example, during a program operation, the row decoder 1260 may apply a program voltage and a program verify voltage to a selected word line, and during a read operation, the row decoder 1260 may apply a read voltage to a selected word line.

In some implementations, the control logic circuit 1220 may include the cancellation management circuit 1221. The cancellation management circuit 1221 may determine whether to operate in a first mode or a second mode in response to a suspend command. The cancellation management circuit 1221 may select a mode, based on a current cancellation count and maximum cancel count of the word line currently being programmed. For example, the current cancellation count may indicate the number of times a program loop was stopped by a suspend command during program execution. The maximum cancel count may indicate the maximum number of times a program loop may be stopped by the suspend command during program execution.

The cancellation management circuit 1221 may perform an adaptive suspend operation, based on physical characteristics. In some implementations, the cancellation management circuit 1221 may perform an adaptive suspend operation, based on the maximum cancel count per word line. The cancellation management circuit 1221 may provide a constant write latency through the adaptive suspend operation.

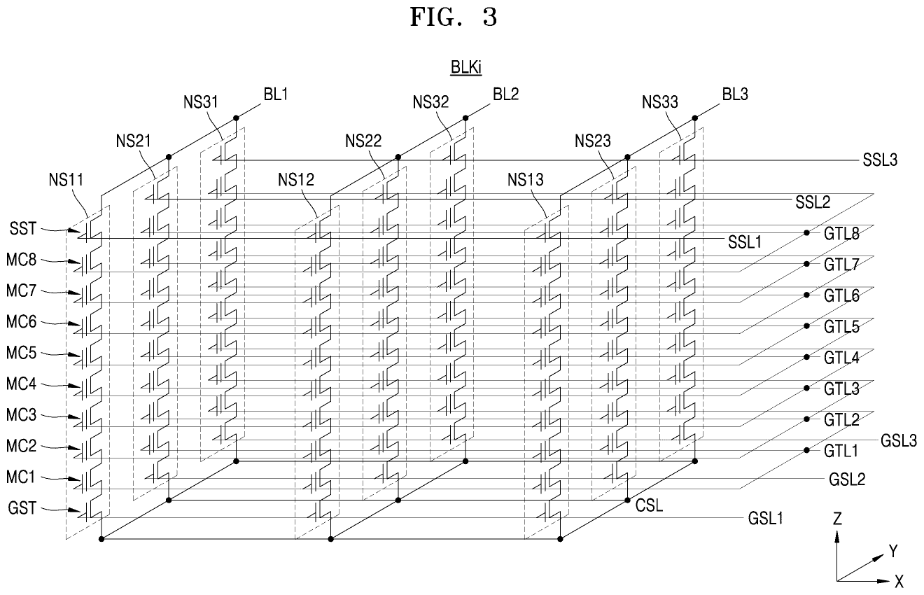

FIG. 3 is a block diagram illustrating an example of a memory block of FIG. 2.

Referring to FIG. 3, a memory block BLKi represents a 3D memory block formed in a 3D structure on a substrate. For example, a plurality of memory NAND strings included in the memory block BLKi may be formed in a direction perpendicular to the substrate.

Referring to FIG. 3, the memory block BLKi may include a plurality of memory NAND strings NS11 to NS33 connected between bit lines BL1, BL2, and BL3 and a common source line CSL. Each of the plurality of memory NAND strings NS11 to NS33 may include a string select transistor SST, a plurality of memory cells MC1, MC2, . . . , MC8, and a ground select transistor GST. In FIG. 3, each of the plurality of memory NAND strings NS11 to NS33 is illustrated as including eight memory cells MC1, MC2, . . . , MC8, but is not necessarily limited thereto.

The string select transistors SST may be connected to corresponding string select lines SSL1, SSL2, and SSL3. The plurality of memory cells MC1, MC2, . . . , MC8 may be respectively connected to corresponding gate lines GTL1, GTL2, . . . , GTL8. The gate lines GTL1, GTL2, . . . , GTL8 may correspond to word lines, and some of the gate lines GTL1, GTL2, . . . , GTL8 may correspond to dummy word lines. The ground select transistor GST may be connected to the corresponding ground select line GSL1, GSL2, and GSL3. The string select transistor SST may be connected to the corresponding bit line BL1, BL2, and BL3, and the ground select transistor GST may be connected to the common source line CSL.

Word lines at the same height (e.g., WL1) may be commonly connected, and ground select lines GSL1, GSL2, and GSL3 and string select lines SSL1, SSL2, and SSL3 may be separated, respectively. In FIG. 3, the memory block BLKi is illustrated as being connected to eight gate lines GTL1, GTL2, . . . , GTL8 and three bit lines BL1, BL2, and BL3, but is not necessarily limited thereto.

Program latency deviation may occur between word lines of the memory block BLKi. Differences in the physical characteristics of memory cells may cause differences in program latency between word lines. Accordingly, the consistency of the write performance of the memory device 1200 may be degraded. A write latency violation or a read latency violation of the memory device 1200 may occur. Due to program latency deviation, performance of the memory device may degrade in mixed I/O patterns in which write and read requests are mixed.

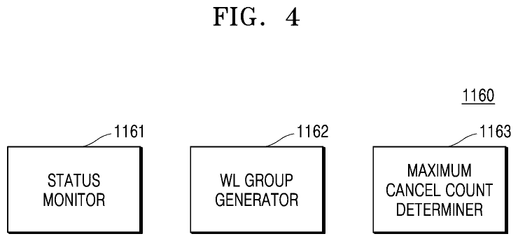

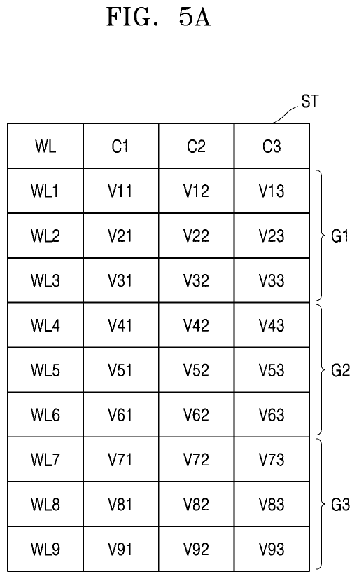

FIG. 4 is a block diagram illustrating the suspend manager of FIG. 1 in more detail. FIGS. 5A to 5C are diagrams illustrating a suspend manager.

Referring to FIGS. 1, 4, and 5A to 5C, the suspend manager 1160 may include a status monitor 1161, a WL group generator 1162, and a maximum cancel count determiner 1163. The status monitor 1161 may perform a monitoring operation. For example, the monitoring operation may refer to an operation of periodically acquiring status information ST of the memory device 1200. The status information ST may indicate physical characteristics of the memory device 1200. Alternatively, the status information ST may refer to information regarding physical characteristics of the memory cells included in the memory device 1200. That is, the status information ST may include physical characteristic information of memory cells. For example, the physical characteristic information may include at least one of program latency (or program time) (tPROG), the number of ISPP loop, an ISPP voltage, an ISPP execution time, and a program/erase (P/E) cycle. In some implementations, the status information ST may include information on the program latency tPROG for each word line.

The status monitor 1161 may obtain the status information ST of the memory device 1200. The status monitor 1161 may provide the status information ST to the WL group generator 1162. The status monitor 1161 may provide the status information ST to the maximum cancel count determiner 1163.

In some implementations, the status monitor 1161 may send a status information request command to the memory device 1200. The memory device 1200 may transmit the status information ST to the status monitor 1161 in response to the status information request command. The status monitor 1161 may receive the status information ST.

In some implementations, the status monitor 1161 may generate the status information ST. The status monitor 1161 may transmit a characteristic information request command to the memory device 1200. The memory device 1200 may transmit characteristic information including physical characteristic data of the memory cells to the status monitor 1161 in response to the characteristic information request command. The status monitor 1161 may receive the characteristic information. The status monitor 1161 may generate the status information ST, based on the characteristic information.

Hereinafter, for convenience of description, the terms “word line,” “memory cells connected to word line,” etc. are used interchangeably. These terms may have the same or different meanings depending on the context of the implementations, and the meaning of each term may be understood according to the context of the implementations being described.

The status information ST may include characteristic information per word line. The status information ST may include a plurality of pieces of physical characteristic data per word line. For example, the status information ST may include pieces of characteristic information C1 to C3 of first to ninth word lines WL1 to WL9. The status information ST may include first to third pieces of characteristic information C1 to C3. For example, the first characteristic information C1 may indicate the program latency tPROG, the second characteristic information C2 may indicate the number of ISPP loops, and the third characteristic information C3 may indicate ISPP execution time tISPP. However, the scope of this disclosure is not limited thereto, and the type and number of physical characteristics included in the status information may change depending on the implementation.

The status information ST may include a plurality of pieces of data V11 to V93. For example, data V11 may indicate the program latency tPROG (or the first characteristic information C1) value of the memory cells of the first word line WL1. Data V12 may indicate the number of ISPP loops (or the second characteristic information C2) value of the memory cells of the first word line WL1. Data V13 may indicate the ISPP execution time tISPP (or the third characteristic information C3) value of the memory cells of the first word line WL1. The other pieces of data V21 to V93 are the same or similar, so a detailed description thereof is omitted.

The WL group generator 1162 may perform a WL grouping operation. The WL grouping operation may refer to an operation of grouping word lines connected to memory cells having identical or similar physical characteristics into the same group. The WL group generator 1162 may perform a WL grouping operation, based on the status information ST. The WL group generator 1162 may perform a WL grouping operation, based on the physical characteristics of memory cells.

The WL group generator 1162 may perform a WL grouping operation, based on the first characteristic information C1. Alternatively, the WL group generator 1162 may perform a WL grouping operation, based on the first to third characteristic information C1 to C3. Below, for convenience of description, the WL grouping operation, based on the first characteristic information C1 is described. It is assumed that memory cells connected to the first to third word lines WL1 to WL3 have similar physical characteristics, memory cells connected to the fourth to sixth word lines WL4 to WL6 have similar physical characteristics, and memory cells connected to the seventh to ninth word lines WL7 to WL9 have similar physical characteristics. That is, the data V11, V21, and V31 are assumed to be similar, the data V41, V51, and V61 are assumed to be similar, and the data V71, V81, and V91 are assumed to be similar.

For example, the WL group generator 1162 may analyze the status information ST and classify similar word lines into the same group. Because the data V11, V21, and V31 are similar, the WL group generator 1162 may classify the first to third word lines WL1 to WL3 into the first group G1. Because the data V41, V51, and V61 are similar, the WL group generator 1162 may classify the fourth to sixth word lines WL4 to WL6 into the second group G2. Because the data V71, V81, and V91 are similar, the WL group generator 1162 may classify the seventh to ninth word lines WL7 to WL9 into the third group G3.

For example, the WL group generator 1162 may classify the first to third word lines WL1 to WL3 having a program latency similar to a first program latency into the first group G1. The WL group generator 1162 may classify the fourth to sixth word lines WL4 to WL6 having a program latency similar to a second program latency into the second group G2. The WL group generator 1162 may classify the seventh to ninth word lines WL7 to WL9 having a program latency similar to a third program latency into the third group G3.

In some implementations, the WL group generator 1162 may generate a WL group map WMAP. For example, the WL group map WMAP may include a mapping relationship between groups and word lines. For example, the WL group generator 1162 may generate a WL group map WMAP for each of the nonvolatile memories. Alternatively, the WL group generator 1162 may generate a WL group map WMAP for each of the plurality of memory blocks. The WL group generator 1162 may receive the status information ST. The WL group generator 1162 may provide the WL group map WMAP to the maximum cancel count determiner 1163. In some implementations, the WL group generator 1162 may transmit the WL group map WMAP to the memory device 1200.

For example, the first group G1 may include first to third word lines WL1 to WL3, the second group G2 may include fourth to sixth word lines WL4 to WL6, and the third group G3 may include seventh to ninth word lines WL7 to WL9. The WL group map WMAP may include first to third entries E1 to E3. The first entry may include a mapping relationship of the first group G1 and the first to third word lines WL1 to WL3, the second entry may include a mapping relationship of the second group G2 and the fourth to sixth word lines WL4 to WL6, and the third entry may include a mapping relationship of the third group G3 and the seventh to ninth word lines WL7 to WL9.

The maximum cancel count determiner 1163 may perform a maximum cancel count determination operation. The maximum cancel count determination operation may refer to an operation of determining the maximum cancel count per group, based on physical characteristics. The maximum cancel count determiner 1163 may determine the maximum cancel count for each group. The maximum cancel count determiner 1163 may receive the WL group map WMAP or the status information ST. The maximum cancel count determiner 1163 may determine the maximum cancel count of each of a plurality of groups, based on the WL group map WMAP or the status information ST. The maximum cancel count determiner 1163 may generate a cancellation count table CT. The maximum cancel count determiner 1163 may transmit the cancellation count table CT to the memory device 1200. For example, the maximum cancel count determiner 1163 may transmit the cancellation count table CT to the memory device 1200 via a set-feature command.

In some implementations, the maximum cancel count determiner 1163 may generate the cancellation count table CT, based on the status information ST or the WL group map WMAP. The cancellation count table CT may include the maximum cancel count of each of a plurality of groups. For example, the cancellation count table CT may include a first maximum cancel count MCC1 which is a maximum cancel count of the first group G1, a second maximum cancel count MCC2 which is a maximum cancel count of the second group G2, and a third maximum cancel count MCC3 which is a maximum cancel count of the third group G3.

The maximum cancel count determiner 1163 may determine the maximum cancel count of the first group G1 as the first maximum cancel count MCC1. The maximum cancel count determiner 1163 may determine the maximum cancel count of the second group G2 as the second maximum cancel count MCC2. The maximum cancel count determiner 1163 may determine the maximum cancel count of the third group G3 as the third maximum cancel count MCC3.

It is assumed that the data V11, V21, and V31 are larger than the data V41, V51, and V61, and the data V41, V51, and V61 are larger than data V71, V81, and V91. The maximum cancel count determiner 1163 may determine the maximum cancel count, based on the characteristic information of the word lines included in each group. For example, the first maximum cancel count MCC1 may be determined based on the first characteristic information C1 of the word lines WL1 to WL3 included in the first group G1.

In some implementations, the maximum cancel count determiner 1163 may determine the maximum cancel count to be a small value when the program latency is long. The maximum cancel count determiner 1163 may determine the maximum cancel count to be a large value when the program latency is short. For example, because the data V11, V21, and V31 is greater than the data V41, V51, and V61, the first maximum cancel count MCC1 may be less than the second maximum cancel count MCC2. Because the data V41, V51, and V61 are greater than the data V71, V81, and V91, the second maximum cancel count MCC2 may be less than the third maximum cancel count MCC3.

Accordingly, the maximum cancel count may be set to be small for word lines with long program latency to prevent the program latency from increasing. The maximum cancel count may be set to be large for word lines with short program latency to improve consistency of the program latency.

As described above, the suspend manager 1160 may adjust the maximum cancel count per word line. The suspend manager 1160 may provide the maximum cancel count per word line (or per group) to the memory device 1200.

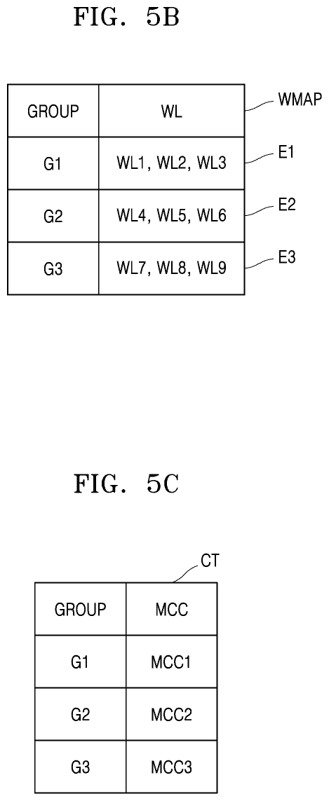

FIG. 6 is a flowchart illustrating an example of an operation of the suspend manager 1160 of FIG. 1.

Referring to FIGS. 1 and 6, the suspend manager 1160 may perform a WL grouping operation and a maximum cancel count determination operation. In operation S110, the suspend manager 1160 may obtain the status information ST. For example, the status information ST may indicate physical characteristic information of the memory device 1200. The suspend manager 1160 may perform a monitoring operation. The suspend manager 1160 may obtain physical characteristic information of the memory device 1200. In some implementations, the suspend manager 1160 may periodically obtain the status information ST.

In operation S120, the suspend manager 1160 may perform a WL grouping operation. The suspend manager 1160 may group a plurality of word lines into a plurality of groups, based on the status information ST. The suspend manager 1160 may perform the WL grouping operation, based on physical characteristics of memory cells. The suspend manager 1160 may group word lines connected to memory cells having identical or similar physical characteristics into the same group. The suspend manager 1160 may generate a WL group map WMAP including mapping relationships between groups and word lines.

In operation S130, the suspend manager 1160 may determine a maximum cancel count. The suspend manager 1160 may perform a maximum cancel count determination operation. The suspend manager 1160 may generate a cancellation count table CT, based on the status information ST or WL group map WMAP. The suspend manager 1160 may determine a maximum cancel count per group. The suspend manager 1160 may determine the maximum cancel count, based on the physical characteristics of the word lines included in a group.

In some implementations, the storage controller 1100 may perform the operations S110 to S130 during an initialization operation. Alternatively, the storage controller 1100 may perform operations S110 to S130 after the initialization operation and before performing a general operation (e.g., including a program operation).

As described above, the storage controller 1100 may perform the WL grouping operation and the maximum cancel count determination operation, based on the physical characteristic information of the memory cells of the memory device 1200. The storage controller 1100 may provide a maximum cancel count to be used in an adaptive suspend operation of the memory device 1200. Accordingly, the overall performance of the storage device 1000 may be improved.

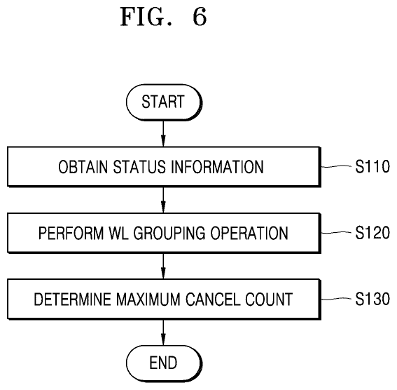

FIG. 7 is a flowchart illustrating an example of an operation of the storage device 1000 of FIG. 1.

Referring to FIGS. 1 and 7, in operation S210, the storage controller 1100 may transmit a status information request command to the memory device 1200. The memory device 1200 may receive the status information request command. In operation S220, the memory device 1200 may transmit the status information ST to the storage controller 1100. The storage controller 1100 may receive the status information ST.

In operation S230, the storage controller 1100 may perform a WL grouping operation. The storage controller 1100 may perform a WL grouping operation, based on the status information ST. The storage controller 1100 may group a plurality of word lines, based on the physical characteristics of memory cells. The storage controller 1100 may classify word lines having similar physical characteristics into the same group. The storage controller 1100 may analyze the status information ST and generate a WL group map WMAP.

In operation S240, the storage controller 1100 may perform a maximum cancel count determination operation. The storage controller 1100 may determine a maximum cancel count for each group. The storage controller 1100 may determine the maximum cancel count, based on the physical characteristics of the word lines included in each group. The storage controller 1100 may generate a cancellation count table CT, based on the status information ST or WL group map WMAP. The cancellation count table CT may contain the maximum cancel count of each group.

In operation S250, the storage controller 1100 may transmit the maximum cancel count to the memory device 1200. For example, the storage controller 1100 may transmit the maximum cancel count to the memory device 1200 via a set-feature command.

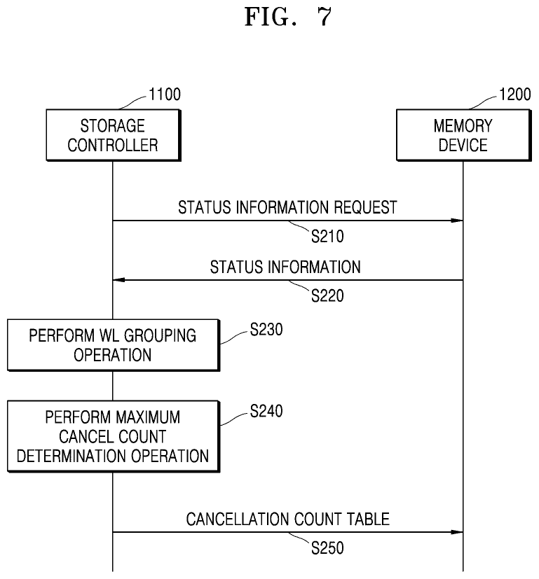

FIG. 8 is a flowchart illustrating an example of the operation of the memory device 1200 of FIG. 1.

Referring to FIGS. 1 and 8, the memory device 1200 may perform a suspend operation in response to a suspend command. The memory device 1200 may perform an adaptive suspend operation. The adaptive suspend operation may refer to an operation of performing one of a first mode or a second mode depending on physical characteristics. For example, the memory device 1200 may operate in a cancel mode, which is the first mode of a suspend operation, for a word line with a relatively short program latency. The memory device 1200 may operate in an on-going mode, which is a second mode of the suspend operation, for word lines with relatively long program latency. For example, the cancel mode may refer to a mode in which the ISPP program loop is stopped without being completed. The on-going mode may refer to a mode in which the ISPP program loop is continued without being stopped.

The memory device 1200 may perform in one of the first mode or the second mode in the suspend operation. The first mode may refer to a mode in which, in response to a suspend command, the program loop being currently executed is immediately stopped and a read operation is performed. The second mode may refer to a mode in which, in response to the suspend command, the program loop being currently executed is continued and a read operation is performed after the program loop is completed.

In operation S310, the memory device 1200 may receive a suspend command. For example, the suspend command may be a command that requests stop of an operation related to a command currently being processed. Alternatively, the suspend command may be a command that requests stop of an operation currently being performed.

In operation S320, the memory device 1200 may compare a current cancellation count CCC and the maximum cancel count MCC. For example, the memory device 1200 may compare the current cancellation count CCC of a first word line, which is a word line corresponding to the command being processed, with the maximum cancel count MCC of a group included in the first word line. If the current cancellation count CCC is less than the maximum cancel count MCC, the memory device 1200 may perform the operation S330, and if the current cancellation count CCC is greater than or equal to the maximum cancel count MCC, the memory device 1200 may perform the operation S340.

In operation S330, the memory device 1200 may operate in the first mode. Because the current cancellation count CCC is less than the maximum cancel count MCC, the memory device 1200 may operate in the first mode of the suspend operation. The memory device 1200 may immediately stop the program loop being currently executed. The memory device 1200 may perform a read operation in response to a read command. The memory device 1200 may immediately stop the program loop and perform the read operation immediately. Accordingly, the memory device 1200 may reduce read latency through the cancel mode which is the first mode. The memory device 1200 may reduce write latency variability.

In operation S340, the memory device 1200 may operate in the second mode. Because the current cancellation count CCC is greater than or equal to the maximum cancel count MCC, the memory device 1200 may operate in the second mode of the suspend operation. The memory device 1200 may continue the program loop being currently executed. After the program loop is completed, the memory device 1200 may perform a read operation in response to a read command. The memory device 1200 may perform the read operation after the program loop is completed without immediately stopping the program loop. Accordingly, the memory device 1200 may improve write consistency through the on-going mode which is the second mode.

As described above, the memory device 1200 may adjust the program latency, based on a maximum cancel count per group or per word line. Accordingly, the memory device 1200 may provide a constant program latency.

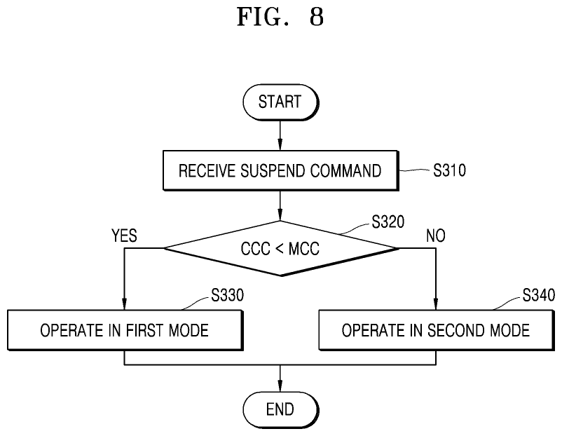

FIG. 9 is a flowchart illustrating an example of the operation of the memory device 1200 of FIG. 1.

Referring to FIGS. 1 and 9, the memory device 1200 may perform an adaptive suspend operation, based on the current cancellation count and the maximum cancel count per group provided from the storage controller 1100. In operation S410, the memory device 1200 may receive a program command. The memory device 1200 may perform a program operation in response to the program command. In some implementations, the memory device 1200 may initialize, in response to a program command, the current cancellation count of word lines of a new memory block (e.g., the first memory block) before starting to program data into the new memory block. For example, the memory device 1200 may set the current cancellation count of a plurality of word lines (e.g., the first to ninth word lines) included in the first memory block to an initialization value before writing data corresponding to a write command to the first memory block. The initialization value may be a predetermined value. The initialization value may be selectively fixed or varied by a designer, manufacturer, and/or user. For example, the memory device 1200 may set the current cancellation count of the first word line of the first memory block to ‘0’and set the current cancellation count of the second word line of the first memory block to '0′. The other word lines (the third to ninth word lines) are the same or similar, so a detailed description is omitted. In operation S420, during a program operation, the memory device 1200 may receive a suspend command.

In operation S430, the memory device 1200 may compare the current cancellation count CCC with the maximum cancel count MCC. The current cancellation count CCC may refer to the current cancellation count corresponding to a word line (e.g., the first word line WL1) during the current program operation. The maximum cancel count MCC may refer to the maximum cancel count MCC corresponding to a word line (e.g., the first word line WL1) during the current program operation. If the current cancellation count CCC is less than the maximum cancel count MCC, the memory device 1200 performs operation S440, and if the current cancellation count CCC is greater than or equal to the maximum cancel count MCC, the memory device 1200 performs operation S460.

In operation S440, the memory device 1200 may operate in the first mode. The memory device 1200 may immediately stop the current program loop and perform a read operation, based on the current cancellation count CCC being less than the maximum cancel count MCC.

In operation S450, the memory device 1200 may increase the current cancellation count CCC. The memory device 1200 may update the current cancellation count CCC. Because the memory device 1200 operates in the cancel mode in response to the suspend command, the current cancellation count CCC may be increased by ‘1’. The memory device 1200 may increase the current cancellation count CCC corresponding to the first word line WL1. Thereafter, the memory device 1200 may perform operation S470.

In operation S460, the memory device 1200 may operate in the second mode. The memory device 1200 may continue to complete the current program loop, based on the current cancellation count CCC being greater than or equal to the maximum cancel count MCC. Thereafter, the memory device 1200 may perform a read operation.

In operation S470, the memory device 1200 may receive a resume command. The memory device 1200 may perform the stopped program operation in response to the resume command. For example, in the first mode, the memory device 1200 may re-perform the stopped program loop. In the second mode, the memory device 1200 may perform a next program loop.

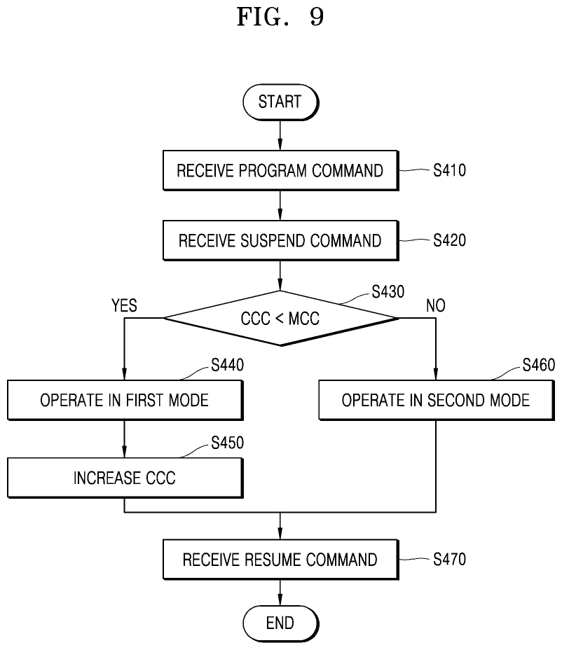

FIG. 10 is a timing diagram illustrating a program operation of the memory device 1200 of FIG. 1.

In FIG. 10, the horizontal axis represents time T and the vertical axis represents voltage V. For example, examples of voltages applied to a word line selected from among the word lines WL during a program operation are shown in FIG. 4. In some implementations, the memory device 1200 may perform a program operation based on an ISPP method.

Referring to FIGS. 1 and 10, the program operation may include a plurality of program loops (or first to n-th program loops) LP1 to LPn. The program operation may be performed by repeating the program loops. As the program loop progresses (or repeats), the level of a program voltage VPGM may increase.

Each of the plurality of program loops LP1 to LPn may include a program that applies the program voltage VPGM and a verification that applies first to seventh verification voltages VFY1 to VFY7.

During the program operation, voltages of the bit lines BL may be set up. For example, the bit lines BL may be connected to selected memory cells (i.e., memory cells that are a target of the program operation) that are connected to selected word lines. A program voltage (e.g., a power supply voltage) may be set up on a bit line connected to memory cells having a threshold voltage to be increased (i.e., to be programmed) among the selected memory cells. A program inhibit voltage (e.g., a ground voltage or a similar low voltage) may be set up on a bit line connected to memory cells having a threshold voltage to be maintained (i.e., program inhibited) among the selected memory cells.

A pass voltage VPASS may be applied to word lines WL. The pass voltage VPASS may turn on memory cells connected to the word lines WL. Thereafter, the program voltage VPGM may be applied to the selected word line. The program voltage VPGM may increase the threshold voltages of the memory cells to be programmed.

During verification, the verification voltages VFY1 to VFY7 may be applied to selected word lines. For example, when 3 bits are programmed in one memory cell, the threshold voltage of one memory cell may be adjusted to (or maintained in) one of an erase state and seven program states by the program operation. The verification voltages VFY1 to VFY7 may be seven voltages corresponding to three program states.

For example, when n-bits (n is a positive integer) are programmed into one memory cell, the threshold voltage of one memory cell may be adjusted (or maintained in) to one of an erased state and 2n−1 program states by the program operation. The verification voltages may be 2n−1 voltages corresponding to 2n−1 program states.

In FIG. 10, the verification voltages VFY1 to VFY7 are shown to be applied in order from a high level voltage to a low level voltage. However, the order in which the verification voltages VFY1 to VFY7 are applied may be independent of the levels of the verification voltages VFY1 to VFY7. Alternatively, the verification voltages VFY1 to VFY7 may be applied in order from a low level voltage to a high level voltage.

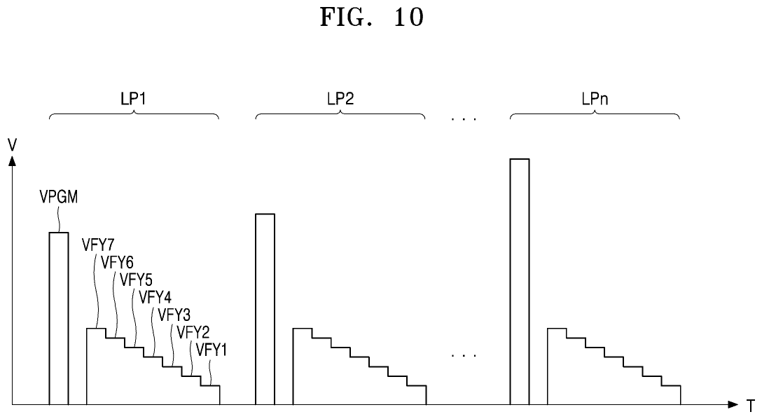

FIG. 11 is a flowchart illustrating the operation S330 of FIG. 8 in detail.

Referring to FIGS. 1, 8, and 11, the memory device 1200 may operate in the first mode of the suspend operation. Operation S330 of FIG. 8 may include operations S331 to S334. It is assumed that the memory device 1200 receives a suspend command during execution of the second program loop LP2. In operation S331, the memory device 1200 may stop a current program loop. For example, the memory device 1200 may stop the second program loop LP2. The memory device 1200 may immediately stop the second program loop LP2 without completing the second program loop LP2.

In operation S332, the memory device 1200 may perform a read operation. The memory device 1200 may receive a read command. The memory device 1200 may perform the read operation in response to the read command. The memory device 1200 may transmit read data read from the memory cell array 1230 to the storage controller 1100.

In operation S333, the memory device 1200 may receive a resume command. The memory device 1200 may receive the resume command from the storage controller 1100. In operation S334, the memory device 1200 may perform the current program loop. For example, the memory device 1200 may re-perform the second program loop LP2 in response to the resume command.

As described above, the memory device 1200 may operate in the first mode or the second mode when the suspend command is received during the program operation based on the maximum cancel count. The memory device 1200 may operate in the cancel mode, which is the first mode, when the current cancellation count is less than the maximum cancel count. The memory device 1200 may immediately stop the currently executed ISPP program loop. In response to the resume command, the memory device 1200 may re-perform the stopped ISPP program loop. Accordingly, the memory device 1200 may provide a constant program latency. Additionally, the memory device 1200 may reduce read latency through the cancel mode which is the first mode. In a mixed input/output pattern, the memory device 1200 may improve the consistency of write performance. The memory device 1200 may provide constant performance.

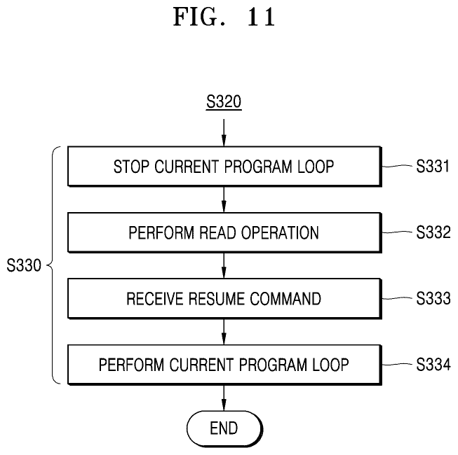

FIG. 12 is a flowchart illustrating the operation S340 of FIG. 8 in detail.

Referring to FIGS. 1, 8, and 12, the memory device 1200 may operate in the second mode of the suspend operation. Operation S340 of FIG. 8 may include operations S341 to S344. It is assumed that the memory device 1200 receives the suspend command during execution of the second program loop LP2. In operation S341, the memory device 1200 may continue the current program loop. For example, the memory device 1200 may continue the second program loop LP2 without a stop. The memory device 1200 may complete the second program loop LP2.

In operation S342, the memory device 1200 may perform a read operation. The memory device 1200 may receive a read command. The memory device 1200 may perform the read operation in response to the read command. The memory device 1200 may transmit read data read from the memory cell array 1230 to the storage controller 1100.

In operation S343, the memory device 1200 may receive a resume command. The memory device 1200 may receive the resume command from the storage controller 1100. In operation S344, the memory device 1200 may perform a next program loop. For example, the memory device 1200 may perform the third program loop LP3 in response to the resume command. Because the memory device 1200 has completed the second program loop LP2 before performing the read operation, the memory device 1200 may perform the third program loop LP3, which is a next loop of the second program loop LP2.

As described above, the memory device 1200 may operate in the on-going mode which is the second mode, when the current cancellation count is greater than the maximum cancel count. The memory device 1200 may continue the currently executed ISPP program loop. In response to the resume command, the memory device 1200 may perform a next ISPP program loop. Accordingly, the memory device 1200 may provide a constant program latency.

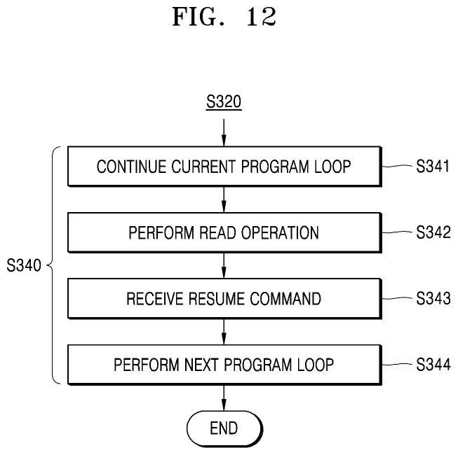

FIG. 13 is a flowchart illustrating an example of the operation of the suspend manager 1160 of FIG. 1.

Referring to FIGS. 1 and 13, the suspend manager 1160 may adjust the WL group map WMAP and the cancellation count table CT. The suspend manager 1160 may adjust the WL group map WMAP or WL group according to changes in the physical characteristics of the memory cells. The suspend manager 1160 may adjust the maximum cancel count per group according to changes in the physical characteristics of the memory cells.

In operation S510, the suspend manager 1160 may perform a monitoring operation. The suspend manager 1160 may perform the monitoring operation during runtime or during operation. The suspend manager 1160 may monitor changes in the physical characteristics of memory cells included in the memory device 1200. The suspend manager 1160 may monitor changes in the physical characteristics of memory cells through the monitoring operation. In some implementations, the suspend manager 1160 may perform the monitoring operation periodically.

In some implementations, the suspend manager 1160 may update status information. The suspend manager 1160 may update the status information to reflect changes in physical characteristics. The suspend manager 1160 may update the status information to include changed characteristic information. The suspend manager 1160 may update the status information based on changes in the physical characteristics of memory cells.

In some implementations, the suspend manager 1160 may periodically transmit a status information request command or a characteristic information request command. The memory device 1200 may transmit the status information to the suspend manager 1160 in response to the status information request command. Alternatively, the memory device 1200 may transmit characteristic information to the suspend manager 1160 in response to the characteristic information request command.

In operation S520, the suspend manager 1160 may detect a status change. The suspend manager 1160 may detect changes in the physical characteristics of memory cells based on updated status information. The suspend manager 1160 may detect a status change when the amount of change in the status information satisfies a preset condition. For example, a preset condition may include a case in which the amount of change in the characteristic information exceeds a threshold. The threshold may be determined in advance. That is, the suspend manager 1160 may determine whether WL group adjustment and maximum cancel count adjustment are necessary based on the change in characteristic information.

In operation S530, the suspend manager 1160 may adjust the WL group. The suspend manager 1160 may adjust the WL group based on the change in physical characteristics. The suspend manager 1160 may update or regenerate the WL group map WMAP based on the updated status information. The suspend manager 1160 may configure word lines connected to memory cells with similar physical characteristics into a same group, based on updated status information.

In operation S540, the suspend manager 1160 may adjust the maximum cancel count. The suspend manager 1160 may adjust the maximum cancel count of each of the plurality of groups based on the change in physical characteristics. The suspend manager 1160 may update or regenerate the cancellation count table, based on the updated status information or the updated WL group map. The suspend manager 1160 may determine the maximum cancel count for each group, based on the updated status information.

As described above, the suspend manager 1160 may adjust the WL group, based on the changed status information. The suspend manager 1160 may adjust the maximum cancel count per group, based on changed status information. The suspend manager 1160 may dynamically change the maximum cancel count per word line in response to the change in physical characteristics. Accordingly, write consistency between word lines may be improved.

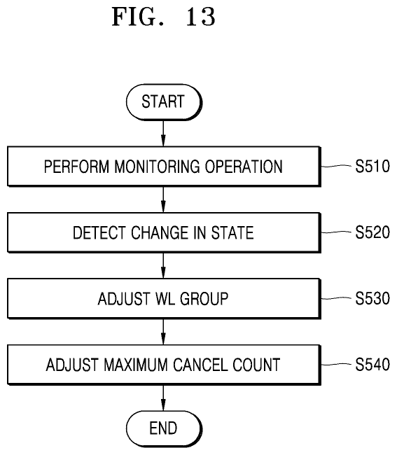

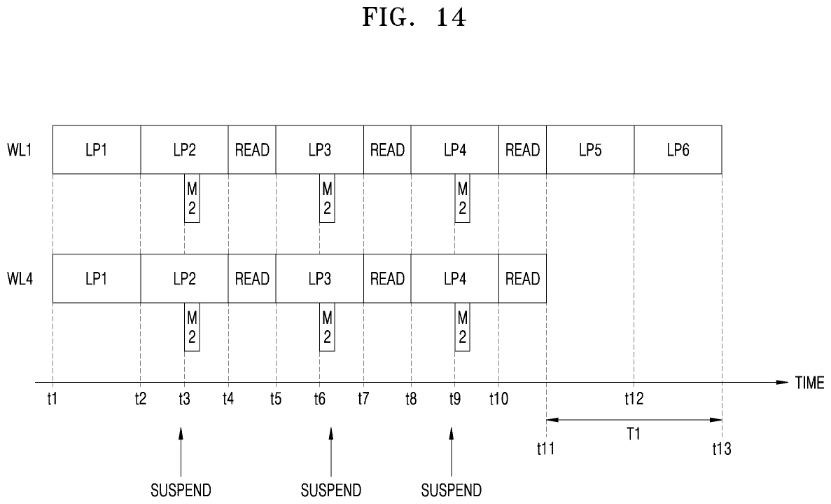

FIGS. 14 and 15 are diagrams illustrating a suspend operation of the memory device 1200 of FIG. 1.

FIG. 14 illustrates a case in which the memory device 1200 performs a general suspend operation, and FIG. 15 illustrates a case in which the memory device 1200 performs an adaptive suspend operation. In other words, FIG. 14 illustrates a case in which the memory device 1200 operates only in the second mode M2, and FIG. 15 illustrates a case in which the memory device 1200 operates in one of the first mode M1 or the second mode M2, based on the maximum cancel count MCC per group.

It is assumed that the first word line WL1 has a first program latency and the fourth word line WL4 has a second program latency. The first word line WL1 may be included in the first group G1, and the fourth word line WL4 may be included in the second group G2. The first program latency may be longer than the second program latency. It is assumed that the first group G1 has a maximum cancel count of ‘0’, and the second group G2 has a maximum cancel count of ‘2’.

Referring to FIG. 14, it is illustrated that a program operation for the first word line WL1 and a program operation for the fourth word line WL4 are performed simultaneously. However, this is an example for comparing the program latency of the first word line WL1 with the program latency of the fourth word line WL4, and it may be understood that, in reality, the program operation of the first word line WL1 and the program operation of the fourth word line WL4 are not performed simultaneously.

At first point in time t1, the memory device 1200 may perform the first program loop LP1 for the first word line WL1. At second point in time t2, the memory device 1200 may perform the second program loop LP2 for the first word line WL1. At third point in time t3, the memory device 1200 may receive a suspend command. The memory device 1200 may operate in the second mode M2 in response to the suspend command. The memory device 1200 may continue the second program loop LP2. The memory device 1200 may complete the second program loop LP2. At fourth point in time t4, the memory device 1200 may perform a read operation. At fourth point in time t4, the memory device 1200 may transmit read data to the storage controller 1100 in response to a read command.

At fifth point in time t5, the memory device 1200 may perform the third program loop LP3 for the first word line WL1. Because the current mode is the second mode M2, the memory device 1200 may perform a next program loop. The memory device 1200 may perform the third program loop LP3 in response to a resume command. At sixth point in time t6, the memory device 1200 may receive a suspend command. The memory device 1200 may operate in the second mode M2 in response to the suspend command. The memory device 1200 may continue the third program loop LP3. The memory device 1200 may complete the third program loop LP3. At seventh point in time t7, the memory device 1200 may perform a read operation. At eighth point in time t8, the memory device 1200 may perform the fourth program loop LP4 for the first word line WL1.

At ninth point in time t9, the memory device 1200 may receive a suspend command. The memory device 1200 may operate in the second mode M2 in response to the suspend command. The memory device 1200 may continue the fourth program loop LP4. The memory device 1200 may complete the fourth program loop LP4. At tenth point in time t10, the memory device 1200 may perform a read operation. At eleventh point in time t11, the memory device 1200 may perform the fifth program loop LP5 for the first word line WL1. At twelfth point in time t12, the memory device 1200 may perform the sixth program loop LP6 for the first word line WL1.

At first point in time t1, the memory device 1200 may perform the first program loop LP1 for the fourth word line WL4. At second point in time t2, the memory device 1200 may perform the second program loop LP2 for the fourth word line WL4. At third point in time t3, the memory device 1200 may receive a suspend command. The memory device 1200 may operate in the second mode M2 in response to the suspend command. The memory device 1200 may continue the second program loop LP2. The memory device 1200 may complete the second program loop LP2. At fourth point in time t4, the memory device 1200 may perform a read operation.

At fifth point in time t5, the memory device 1200 may perform the third program loop LP3 for the fourth word line WL4. At sixth point in time t6, the memory device 1200 may receive a suspend command. The memory device 1200 may operate in the second mode M2 in response to the suspend command. The memory device 1200 may continue the third program loop LP3. The memory device 1200 may complete the third program loop LP3. At seventh point in time t7, the memory device 1200 may perform a read operation. At eighth point in time t8, the memory device 1200 may perform the fourth program loop LP4 for the fourth word line WL4.

At ninth point in time t9, the memory device 1200 may receive a suspend command. The memory device 1200 may operate in the second mode M2 in response to the suspend command. The memory device 1200 may continue the fourth program loop LP4. The memory device 1200 may complete the fourth program loop LP4. At tenth point in time t10, the memory device 1200 may perform a read operation.

At thirteenth point in time t13, the program operation for the first word line WL1 may be completed, and at eleventh point in time t11, the program operation for the fourth word line WL4 may be completed. A difference in program latency between the first word line WL1 and the fourth word line WL4 may be first time T1.

Referring to FIG. 15, it is illustrated that a program operation for the first word line WL1 and a program operation for the fourth word line WL4 are performed simultaneously. However, this is an example for comparing the program latency of the first word line WL1 with the program latency of the fourth word line WL4, and it may be understood that, in reality, the program operation of the first word line WL1 and the program operation of the fourth word line WL4 are not performed simultaneously.

At first point in time t1, the memory device 1200 may perform the first program loop LP1 for the first word line WL1. At second point in time t2, the memory device 1200 may perform the second program loop LP2 for the first word line WL1. At third point in time t3, the memory device 1200 may receive a suspend command. The maximum cancel count of the first group G1 including the first word line WL1 is ‘0’and the current cancellation count of the first word line WL1 is ‘0’, so the current cancellation count is greater than or equal to the maximum cancel count, and therefore, the memory device 1200 may operate in the second mode. The memory device 1200 may continue the second program loop LP2. The memory device 1200 may complete the second program loop LP2. At fourth point in time t4, the memory device 1200 may perform a read operation. At fourth point in time t4, the memory device 1200 may transmit read data to the storage controller 1100 in response to the read command.

At fifth point in time t5, the memory device 1200 may perform the third program loop LP3 for the first word line WL1. Because the current mode is the second mode M2, the memory device 1200 may perform a next program loop. The memory device 1200 may perform the third program loop LP3 in response to a resume command. At sixth point in time t6, the memory device 1200 may receive a suspend command. Because the current cancellation count is greater than or equal to the maximum cancel count, the memory device 1200 may operate in the second mode. The memory device 1200 may continue the third program loop LP3. The memory device 1200 may complete the third program loop LP3. At seventh point in time t7, the memory device 1200 may perform a read operation. At eighth point in time t8, the memory device 1200 may perform the fourth program loop LP4 for the first word line WL1.

At ninth point in time t9, the memory device 1200 may receive a suspend command. Because the current cancellation count is greater than or equal to the maximum cancel count, the memory device 1200 may operate in the second mode. The memory device 1200 may continue the fourth program loop LP4. The memory device 1200 may complete the fourth program loop LP4. At tenth point in time t10, the memory device 1200 may perform a read operation. At eleventh point in time t11, the memory device 1200 may perform the fifth program loop LP5 for the first word line WL1. At twelfth point in time t12, the memory device 1200 may perform the sixth program loop LP6 for the first word line WL1.

At first point in time t1, the memory device 1200 may perform the first program loop LP1 for the fourth word line WL4. At second point in time t2, the memory device 1200 may perform the second program loop LP2 for the fourth word line WL4. At third point in time t3, the memory device 1200 may receive a suspend command. Because the current cancellation count of the fourth word line WL4 is ‘0’and the maximum cancel count of the second group G2 including the fourth word line WL4 is ‘2’, the memory device 1200 may operate in the first mode M1. The current cancellation count may be updated to ‘1’. The memory device 1200 may immediately stop the second program loop LP2. At third point in time t3, the memory device 1200 may perform a read operation.

At fourth point in time t4, the memory device 1200 may perform the second program loop LP2 for the fourth word line WL4. Because the memory device 1200 has stopped the second program loop LP2 in response to the suspend command, the second program loop LP2 may be re-performed.

At fourteenth point in time t14, the memory device 1200 may perform the third program loop LP3 for the fourth word line WL4. At sixth point in time t6, the memory device 1200 may receive a suspend command. Because the current cancellation count of the fourth word line WL4 is ‘1’and the maximum cancel count of the second group G2 including the fourth word line WL4 is ‘2’, the memory device 1200 may operate in the first mode M1. The current cancellation count may be updated to ‘2’. The memory device 1200 may immediately stop the third program loop LP3. At sixth point in time t6, the memory device 1200 may perform a read operation. At fifteenth point in time t15, the memory device 1200 may perform the third program loop LP3 again for the fourth word line WL4. The memory device 1200 may re-perform the third program loop LP3 that has been stopped.

At ninth point in time t9, the memory device 1200 may receive a suspend command. Because the current cancellation count of the fourth word line WL4 is ‘2’and the maximum cancel count of the second group G2 including the fourth word line WL4 is ‘2’, the memory device 1200 may operate in the second mode M2. The memory device 1200 may continue the third program loop LP3. The memory device 1200 may complete the third program loop LP3. At sixteenth point in time t16, the memory device 1200 may perform a read operation. At seventeenth point in time t17, the fourth program loop LP4 may be performed for the fourth word line WL4.

At thirteenth point in time t13, the program operation for the first word line WL1 may be completed, and at eighteenth point in time t18, the program operation for the fourth word line WL4 may be completed. A difference in program latency between the first word line WL1 and the fourth word line WL4 may be second time T2. The second time T2 may be shorter than the first time T1.

For a group with short program latency, write consistency may be improved by setting a larger maximum cancel count, compared to a group with long program latency. A group with a shorter program latency may operate in the first mode more often than a group with a longer program latency, i.e. the number of times the program loop being currently executed is stopped may increase, thereby increasing program latency. Accordingly, the overall deviation in program latency between word lines may be reduced.

In FIG. 14, because the memory device 1200 constantly performed in the second mode, the program latency deviation between the first and fourth word lines was large. However, the memory device 1200 according to some implementations may operate in one of the first mode or the second mode for each word line, based on the maximum cancel count set based on physical characteristics. Accordingly, the program latency deviation (or difference) between the first and fourth word lines may be effectively reduced.

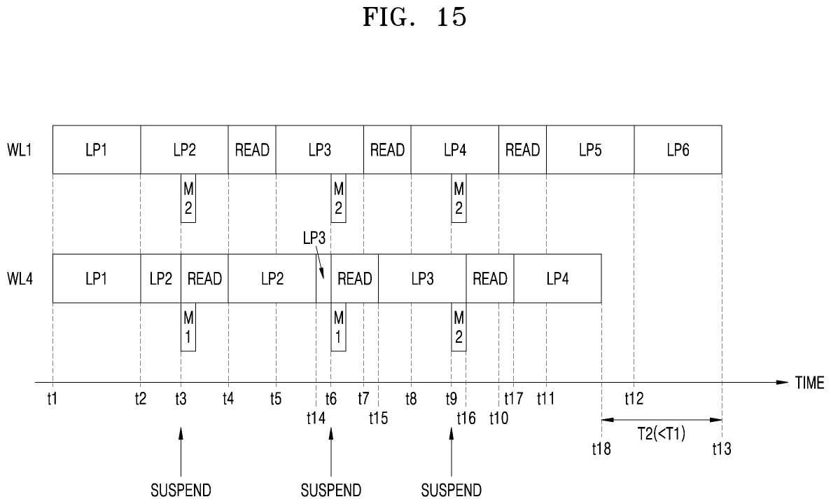

FIG. 16 is a graph illustrating an example of the relationship between word lines and characteristic information in the memory device 1200 of FIG. 1.

In the graph of FIG. 16, the horizontal axis represents word lines, the vertical axis represents time (or program latency) for the solid line and represents the number of times a loop is executed (or the number of ISPP program loops) for dashed line. An example of program latency is shown in the solid line, and the number of ISPP program loops is shown in the dashed line. Referring to the graph, it can be seen that there is a deviation in the number of ISPP program loops and program latency by word line, and it can be seen that trend of the number of ISPP loops is similar to the trend of the program latency. The number of loops of ISPP and program latency show similar patterns.

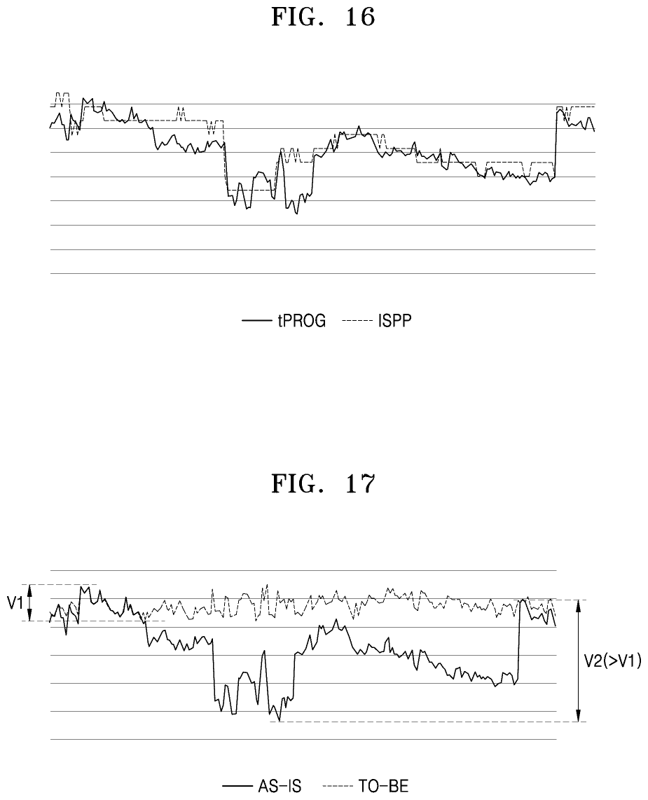

FIG. 17 is a graph illustrating the effect of an adaptive suspend operation.

In the graph of FIG. 17, the horizontal axis represents word lines and the vertical axis represents program latency. An example of the adaptive suspend operation according to some implementations is illustrated in the dotted line, and an example of a general suspend operation that operates only in the second mode is illustrated in the solid line.

Referring to the dotted line, the maximum difference in program latency may be a first value V1 for the adaptive suspend operation. Referring to the solid line, the maximum difference in program latency may be a second value V2 without the adaptive suspend operation. The second value V2 may be greater than the first value V1. By performing the adaptive suspend operation according to some implementations, the variability of program latency may be reduced. That is, the write consistency of the memory device 1200 may be improved.

In the mixed input/output pattern as in FIG. 17, the storage device 1000 may adjust the maximum cancel count according to the physical characteristics of the memory cells and perform the adaptive suspend operation. The storage device 1000 may provide consistent performance in the mixed input/output pattern. The storage device 1000 may reduce program latency deviation between word lines and improve write consistency.

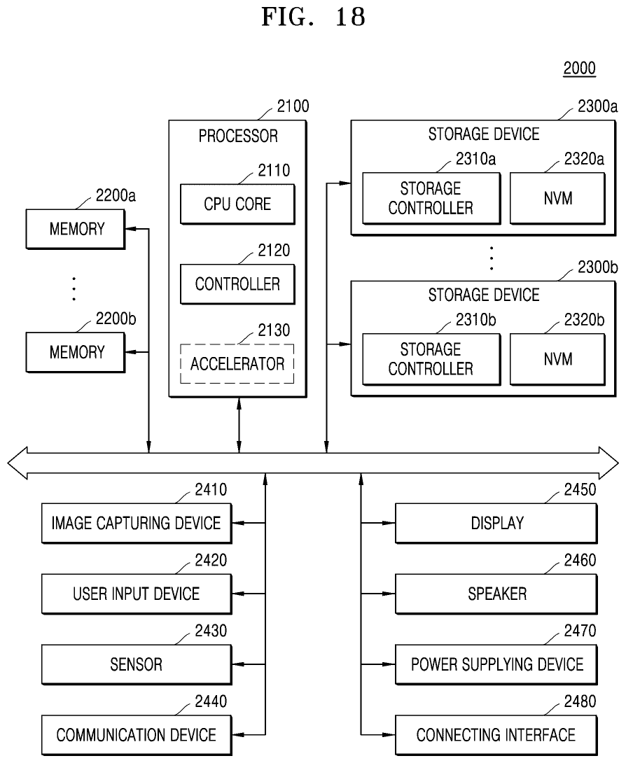

FIG. 18 is a diagram of a system 2000 to which a storage device is applied, according to some implementations.

The system 2000 of FIG. 18 may basically be a mobile system, such as a portable communication terminal (e.g., a mobile phone), a smartphone, a tablet personal computer (PC), a wearable device, a healthcare device, or an Internet of things (IOT) device. However, the system 2000 of FIG. 18 is not necessarily limited to the mobile system and may be a PC, a laptop computer, a server, a media player, or an automotive device (e.g., a navigation device).

Referring to FIG. 18, the system 2000 may include a main processor 2100, memories (e.g., 2200a and 2200b), and storage devices (e.g., 2300a and 2300b). In addition, the system 2000 may include at least one of an image capturing device 2410, a user input device 2420, a sensor 2430, a communication device 2440, a display 2450, a speaker 2460, a power supplying device 2470, and a connecting interface 2480.

The main processor 2100 may control all operations of the system 2000, more specifically, operations of other components included in the system 2000. The main processor 2100 may be implemented as a general-purpose processor, a dedicated processor, or an application processor.

The main processor 2100 may include at least one CPU core 2110 and further include a controller 2120 configured to control the memories 2200a and 2200b and/or the storage devices 2300a and 2300b. In some implementations, the main processor 2100 may further include an accelerator 2130, which is a dedicated circuit for a high-speed data operation, such as an artificial intelligence (AI) data operation. The accelerator 2130 may include a graphics processing unit (GPU), a neural processing unit (NPU) and/or a data processing unit (DPU) and be implemented as a chip that is physically separate from the other components of the main processor 2100.

The memories 2200a and 2200b may be used as main memory devices of the system 2000. Although each of the memories 2200a and 2200b may include a volatile memory, such as static random access memory (SRAM) and/or dynamic RAM (DRAM), each of the memories 2200a and 2200b may include nonvolatile memory, such as a flash memory, phase-change RAM (PRAM) and/or resistive RAM (RRAM). The memories 2200a and 2200b may be implemented in the same package as the main processor 2100.

The storage devices 2300a and 2300b may serve as nonvolatile storage devices configured to store data regardless of whether power is supplied thereto, and have larger storage capacity than the memories 2200a and 2200b. The storage devices 2300a and 2300b may respectively include storage controllers (STRG CTRL) 2310a and 2310b and NVM (Nonvolatile Memory)s 2320a and 2320b configured to store data via the control of the storage controllers 2310a and 2310b. Although the NVMs 2320a and 2320b may include flash memories having a two-dimensional (2D) structure or a 3D (3D) V-NAND structure, the NVMs 2320a and 2320b may include other types of NVMs, such as PRAM and/or RRAM.

The storage devices 2300a and 2300b may be physically separated from the main processor 2100 and included in the system 2000 or implemented in the same package as the main processor 2100. In addition, the storage devices 2300a and 2300b may have types of solid-state devices (SSDs) or memory cards and be removably combined with other components of the system 2000 through an interface, such as the connecting interface 2480 that will be described below. The storage devices 2300a and 2300b may be devices to which a standard protocol, such as a universal flash storage (UFS), an embedded multi-media card (eMMC), or a nonvolatile memory express (NVMe), is applied, without being limited thereto.

The image capturing device 2410 may capture still images or moving images. The image capturing device 2410 may include a camera, a camcorder, and/or a webcam.

The user input device 2420 may receive various types of data input by a user of the system 2000 and include a touch pad, a keypad, a keyboard, a mouse, and/or a microphone.

The sensor 2430 may detect various types of physical quantities, which may be obtained from the outside of the system 2000, and convert the detected physical quantities into electric signals. The sensor 2430 may include a temperature sensor, a pressure sensor, an illuminance sensor, a position sensor, an acceleration sensor, a biosensor, and/or a gyroscope sensor.

The communication device 2440 may transmit and receive signals between other devices outside the system 2000 according to various communication protocols. The communication device 2440 may include an antenna, a transceiver, and/or a modem.

The display 2450 and the speaker 2460 may serve as output devices configured to respectively output visual information and auditory information to the user of the system 2000.

The power supplying device 2470 may appropriately convert power supplied from a battery (not shown) embedded in the system 2000 and/or an external power source, and supply the converted power to each of components of the system 2000.

The connecting interface 2480 may provide connection between the system 2000 and an external device, which is connected to the system 2000 and capable of transmitting and receiving data to and from the system 2000. The connecting interface 2480 may be implemented by using various interface schemes, such as advanced technology attachment (ATA), serial ATA (SATA), external SATA (e-SATA), small computer small interface (SCSI), serial attached SCSI (SAS), peripheral component interconnection (PCI), PCI express (PCIe), NVMe, IEEE 1394, a universal serial bus (USB) interface, a secure digital (SD) card interface, a multi-media card (MMC) interface, an eMMC interface, a UFS interface, an embedded UFS (eUFS) interface, and a compact flash (CF) card interface.

In some implementations, the storage device (2300a, 2300b) may be the storage device 1000 described with reference to FIGS. 1 to 17. The storage controller (2310a, 2310b) may be the storage controller 1100 described with reference to FIGS. 1 to 17. The storage controller (2310a, 2310b) may include a suspend manager. The storage controller (2310a, 2310b) may perform WL grouping operations and maximum cancel count determination operations based on physical characteristics. The nonvolatile memory NVM (2320a, 2320b) may be the memory device 1200 described with reference to FIGS. 1 to 17. Nonvolatile memory NVM (2320a, 2320b) may include a cancellation management circuit 1221. Nonvolatile memory NVM (2320a, 2320b) may perform adaptive suspend operation.

In some implementations, the storage device (2300a, 2300b) may group word lines based on physical characteristics of the NAND. The storage devices (2300a, 2300b) may adjust the maximum cancel count used in adaptive suspend operation on a group-by-group basis. Accordingly, the storage device (2300a, 2300b) may reduce program latency deviation between word lines and improve write consistency.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While this disclosure has been particularly shown and described with reference to implementations thereof, it will be understood that various changes in form and details may be made therein without departing from the spirit and scope of the following claims.

What is claimed is:

1. An operating method of a storage device including a storage controller and a memory device, the operating method comprising:
performing, by the storage controller, a word line grouping operation of word lines connected to memory cells, wherein performing the word line grouping operation comprises classifying the word lines into one or more groups based on status information, wherein each group of the one or more groups comprises word lines having similar physical characteristics;
determining, by the storage controller, a maximum cancel count of each group of the one or more groups;
receiving, by the memory device, a suspend command;
comparing, by the memory device, a current cancellation count of a first word line corresponding to the suspend command with a maximum cancel count of a first group that includes the first word line;
operating, by the memory device, in a first mode of a suspend operation based on the current cancellation count being less than the maximum cancel count of the first group, or operating, by the memory device, in a second mode of the suspend operation based on the current cancellation count being greater than or equal to the maximum cancel count of the first group,
wherein operating in the first mode comprises stopping a currently executed program loop and performing a read operation, and wherein operating in the second mode comprises continuing the currently executed program loop and performing the read operation after completion of the program loop.

2. The operating method of claim 1, comprising:
transmitting, by the storage controller, a status information request to the memory device; and
receiving, by the storage controller, the status information from the memory device.

3. The operating method of claim 1, wherein
determining the maximum cancel count of each group of the one or more groups comprises:
generating a cancellation count table including the maximum cancel count of each group of the one or more groups; and
transmitting the cancellation count table to the memory device.

4. The operating method of claim 3, wherein transmitting the cancellation count table to the memory device comprises transmitting the cancellation count table to the memory device via a set-feature command.

5. The operating method of claim 1, comprising:
generating, by the storage controller, a word line group map; and
transmitting, by the storage controller, the word line group map to the memory device.

6. The operating method of claim 1, wherein operating in the first mode of the suspend operation comprises increasing the current cancellation count.

7. The operating method of claim 1, wherein
performing the word line grouping operation comprises:
classifying the first word line through a third word line into the first group, wherein each of the first word line through the third word line has a program latency similar to a first program latency; and
classifying a fourth word line through a sixth word line into a second group, wherein each of the fourth word line through the sixth word line has a program latency similar to a second program latency.

8. The operating method of claim 7, wherein
determining the maximum cancel count of each group of the one or more groups comprises:
determining the maximum cancel count of the first group to be a first maximum cancel count; and
determining the maximum cancel count of a second group to be a second maximum cancel count,
wherein the first program latency is longer than the second program latency, and the first maximum cancel count is less than the second maximum cancel count.

9. The operating method of claim 1, wherein the status information comprises physical characteristic information of memory cells, and the physical characteristic information comprises a program latency, a number of incremental step pulse programming (ISPP) program loops, an ISPP voltage, an ISPP execution time, and/or a program/erase cycle.

10. The operating method of claim 1, wherein the currently executed program loop is a first program loop,
wherein receiving the suspend command comprises receiving the suspend command while performing the first program loop in a program operation, and
wherein operating in the first mode comprises:
receiving a resume command; and
re-performing the first program loop based on the resume command.

11. The operating method of claim 1, wherein the currently executed program loop is a first program loop, wherein receiving the suspend command comprises receiving the suspend command while performing the first program loop in a program operation, and
operating in the second mode comprises:
receiving a resume command; and
performing a second program loop based on the resume command.

12. The operating method of claim 1, comprising:
performing a monitoring operation to obtain the status information;
detecting a change in the physical characteristics of the memory cells, based on the status information;
adjusting at least one group of the one or more groups, based on the change in the physical characteristics; and
adjusting the maximum cancel count of the at least one group of the one or more groups, based on the change in the physical characteristics.

13. A storage device comprising:
a memory device; and
a storage controller configured to control the memory device and communicate with an external host, the storage controller comprising a suspend manager circuit,
wherein the suspend manager circuit comprises
a status monitor configured to obtain status information,
a word line group generation circuit configured to perform a word line grouping operation to classify, based on status information, word lines into one or more groups, wherein each group of the one or more groups comprises word lines having similar physical characteristics, and wherein the word lines are connected to memory cells, and
a maximum cancel count determination circuit configured to determine a maximum cancel count of each group of the one or more groups,
wherein the memory device is configured to
receive a suspend command from the storage controller,
compare a current cancellation count of a first word line corresponding to the suspend command with a maximum cancel count of a first group including the first word line,
operate in a first mode of a suspend operation based on the current cancellation count being less than the maximum cancel count, and
operate in a second mode of the suspend operation based on the current cancellation count being greater than or equal to the maximum cancel count, and
wherein, in the first mode, the memory device is configured to stop a currently executing program loop and perform a read operation, and
in the second mode, the memory device is configured to continue the currently executing program loop and perform a read operation after completion of the currently executing program loop.

14. The storage device of claim 13, wherein the storage controller is configured to transmit a status information request to the memory device and receive the status information from the memory device.

15. The storage device of claim 13, wherein the storage controller is configured to generate a cancellation count table including the maximum cancel count of each group of the one or more groups, and to transmit the cancellation count table to the memory device.

16. The storage device of claim 13, wherein
the status information comprises physical characteristic information of memory cells, and the physical characteristic information comprises a program latency, a number of incremental step pulse programming (ISPP) program loops, an ISPP voltage, an ISPP execution time, and/or a program/erase cycle.

17. The storage device of claim 13, wherein
the memory device is configured to receive a suspend command while performing the first program loop in a program operation, and
the memory device is configured to, based on the current cancellation count being less than the maximum cancel count, stop the first program loop, perform a read operation, receive a resume command, and re-perform the first program loop in response to the resume command.

18. The storage device of claim 13, wherein
the memory device is configured to receive a suspend command while performing the first program loop in a program operation, and
the memory device is configured to, based on the current cancellation count being greater than or equal to the maximum cancel count, continue the first program loop, perform a read operation after the first program loop is completed, receive a resume command, and perform a second program loop in response to the resume command.

19. An operating method of a storage controller, the operating method comprising:
obtaining status information comprising physical characteristic information of memory cells of an external memory device;
performing a word line grouping operation, wherein performing the word line grouping operation comprises classifying, based on the status information, word lines into one or more groups, wherein each group of the one or more groups comprises word lines having similar physical characteristics; and
determining a maximum cancel count of each group of the one or more groups of word lines.

20. The operating method of claim 19, wherein
determining the maximum cancel count of each group of the one or more groups comprises:
generating a cancellation count table including a maximum cancel count of each group of the one or more groups; and
transmitting the cancellation count table to the external memory device.
